(19) United States
(12) Patent Application Publication
(10) Pub. No.: US 2026/0238221 A1
(43) Pub. Date: Aug. 13, 2026

(54) CURRENT-MODE DIGITAL-TO-ANALOG CONVERTER (DAC) INTERFACE FOR MULTI-PHASE SIGNAL GENERATION

(71) Applicant: QUALCOMM Incorporated, San Diego, CA (US)

(72) Inventors: Ibrahim Ramez CHAMAS, Carlsbad, CA (US); Bhushan Shanti ASURI, San Diego, CA (US); Shahin MEHDIZAD TALEIE, San Diego, CA (US)

(21) Appl. No.: 19/049,419

(22) Filed: Feb. 10, 2025

(51) Int. Cl. H03M 1/66

(52) U.S. Cl. CPC H03M 1/661; H03M 1/662

(57) ABSTRACT

Certain aspects of the present disclosure generally relate to electronic components and, more particularly, to circuitry for phase interpolation. An example apparatus for phase interpolation generally includes: digital-to-analog converter (DAC) circuitry configured to generate at least two in-phase (I) currents, at least two complementary I (IB) currents, at least two quadrature (Q) currents, and at least two complementary Q (QB) currents; and an interpolator configured to split each of the at least two I currents, the at least two IB currents, the at least two Q currents, and the at least two QB currents to generate a plurality of phase-shifted currents.

### BACKGROUND

### Field of the Disclosure

Certain aspects of the present disclosure generally relate to electronic components and, more particularly, to circuitry for phase interpolation.

### Description of Related Art

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system). Wireless devices may include transmitters for processing signals for transmission via antennas. A transmitter may include one or more digital-to-analog converters (DACs) for converting signals from the digital domain to the analog domain for processing to facilitate transmissions.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards an apparatus for phase interpolation. The apparatus generally includes: digital-to-analog converter (DAC) circuitry configured to generate at least two in-phase (I) currents, at least two complementary I (IB) currents, at least two quadrature phase (Q) currents, and at least two complementary Q (QB) currents; and an interpolator configured to split each of the at least two I currents, at least two IB currents, at least two Q currents, and at least two QB currents to generate a plurality of phase-shifted currents.

Certain aspects of the present disclosure are directed towards an apparatus for phase interpolation. The apparatus generally includes: current-mode DAC circuitry including at least two I outputs, at least two IB outputs, at least two Q outputs, and at least two QB outputs; and a current-mode interpolator including multiple inputs, wherein at least a subset of the multiple inputs are coupled to the at least two I outputs, at least two IB outputs, at least two Q outputs, and at least two QB outputs respectively, wherein the current-mode interpolator includes split current paths coupled to each of the multiple inputs.

Certain aspects of the present disclosure are directed towards a method for phase interpolation. The method generally includes: generating, via DAC circuitry, at least two I currents, at least two IB currents, at least two Q currents, and at least two QB currents; and split, via an interpolator, each of the at least two I currents, at least two IB currents, at least two Q currents, and at least two QB currents to generate a plurality of phase-shifted currents.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in which certain aspects of the present disclosure may be practiced.

FIG. 2 is a block diagram of an example access point (AP) and example user terminals, in which certain aspects of the present disclosure may be practiced.

FIG. 3 is a block diagram of an example transceiver front end, in which certain aspects of the present disclosure may be practiced.

FIG. 4 is a block diagram of an example transmitter with in-phase (I) and quadrature (Q) paths.

FIG. 5 is a graph showing various harmonic signals around an operating band of a transmitter.

FIG. 6 is a block diagram of an example transmitter including current-mode digital-to-analog converters (DACs) with a current-mode interpolator, in accordance with certain aspects of the present disclosure.

FIG. 7 is a block diagram of example digital-to-analog conversion circuitry configured to generate currents using current splitting with buffers, in accordance with certain aspects of the present disclosure.

FIG. 8 illustrates I and Q DACs, each including two DAC cores to generate one-half full-scale currents, in accordance with certain aspects of the present disclosure.

FIG. 9 is a block diagram of example current-steering cells of a DAC, in accordance with certain aspects of the present disclosure.

FIG. 10 is a circuit diagram of an example current-mode resistive interpolator, in accordance with certain aspects of the present disclosure.

FIG. 11 is a flow diagram illustrating example operations for phase interpolation, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards performing current-mode interpolation at an interface between digital-to-analog conversion circuitry and baseband filter (BBF) circuitry of a transmitter. The interpolation may be used to generate in-phase (I), quadrature (Q), I with a 45° phase offset (I45), and Q with a 45° phase offset (Q45) signals that result in increasing the linearization of the succeeding circuit.

Some implementations use interpolation at the interface between the BBFs and mixers of the transmitter. However, this approach provides a low-impedance node at the output of an interpolator that may result in using a large capacitive element for signal filtering, causing increased area consumption for the transmitter. Interpolation at the interface between the BBFs and the mixers may also result in signal loss. Some aspects of the present disclosure implement a linearization interface with interpolation starting at the interface between digital-to-analog converters (DACs) and BBFs to generate the I, I45, Q, Q45 signals. No interpolation may be used at the interface between the BBFs and mixers. The current-mode interpolator may provide little to no signal loss since the generated current is scaled, rotated, and steered into the BBF circuitry, as described in more detail herein. In some aspects, digital-to-analog conversion circuitry may be used to generate duplicate I, Q, I45, and Q45 currents that enable current-mode interpolation. The current-mode interpolation may be implemented using split paths to split the currents generated by the digital-to-analog conversion circuitry, as described in more detail herein.

The transmitter described herein may be implemented for a base station transceiver chip, in some cases. However, the transmitted may be implemented for any suitable device such as a user equipment (UE).

### Example Wireless Communications

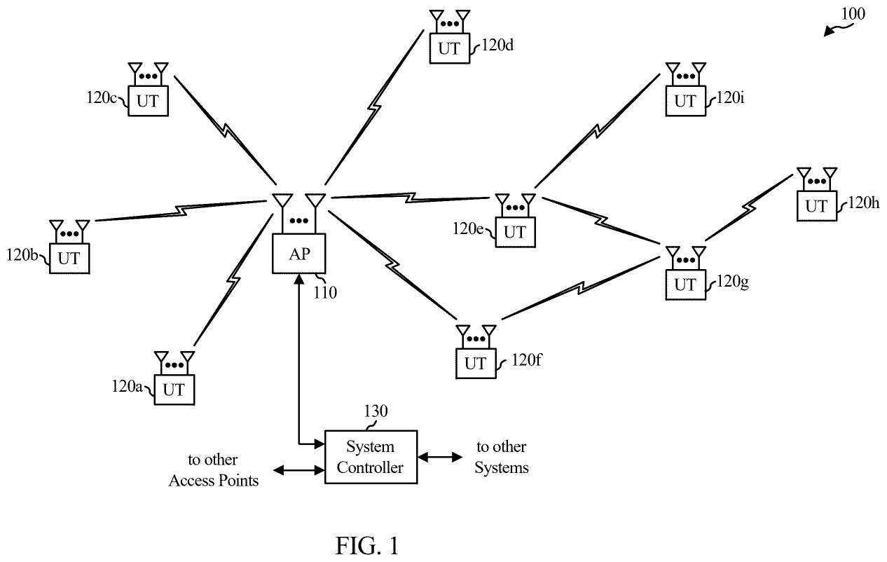

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported).

In some aspects, the user terminal 120 or access point 110 may include a current-mode interpolator at an interface between digital-to-analog conversion circuitry and baseband filters (BBFs), as described in more detail herein.

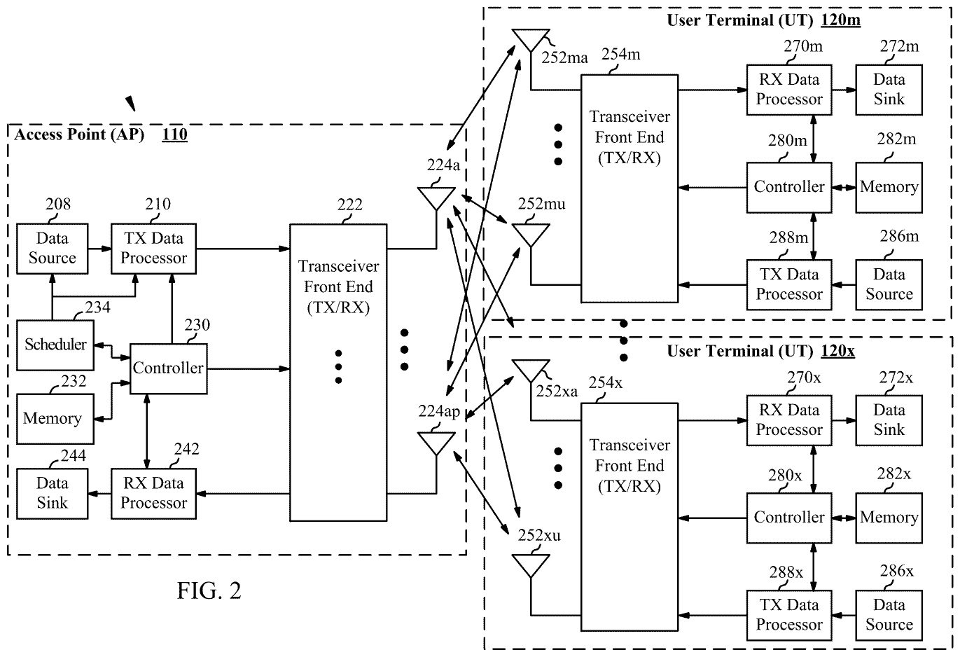

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut, x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a transmitter (TX) data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ}for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. A receiver (RX) data processor 242 processes (e.g., demodulates, deinterleaves, and decodes) the recovered uplink data symbol stream in accordance with the rate used for that stream to obtain decoded data. The decoded data for each user terminal may be provided to a data sink 244 (e.g., corresponding to data sink 272 of UT) for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

In some aspects, the transceiver front end 254 or 222 may include a current-mode interpolator at an interface between digital-to-analog conversion circuitry and baseband filters (BBFs), as described in more detail herein.

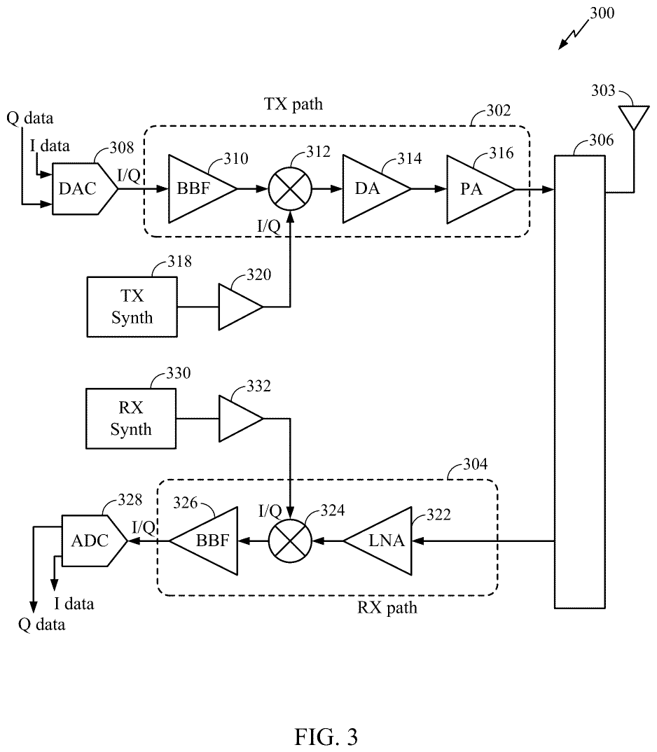

FIG. 3 is a block diagram of an example transceiver front end 300, such as transceiver front ends 222, 254 in FIG. 2, in which aspects of the present disclosure may be practiced. The transceiver front end 300 includes at least one transmit (TX) path 302 (also known as a transmit chain) for transmitting signals via one or more antennas and at least one receive (RX) path 304 (also known as a receive chain) for receiving signals via the one or more antennas. When the TX path 302 and the RX path 304 share an antenna 303, the paths may be connected with the antenna via an interface 306, which may include any of various suitable RF devices, such as a switch, a duplexer, a diplexer, a multiplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, the DA 314, and the PA 316 may be included in a radio frequency integrated circuit (RFIC). In some cases, the PA 316 may be external to the RFIC. In some cases, the DA 314 may include a pre-DA that may drive a DA, where the DA drives the PA 316.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies of the LO frequency and the frequencies of the baseband signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303. While one mixer 312 is illustrated, several mixers may be used to upconvert the filtered baseband signals to one or more intermediate frequencies and to thereafter upconvert the intermediate frequency (IF) signals to a frequency for transmission. In some aspects, an interpolation interface may be implemented between the DAC 308 and the BBF 310. The interpolation interface may include a current-mode interpolator, as described in more detail herein.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (e.g., downconvert). The baseband signals output by the mixer 324 may be filtered by the BBF 326 before being converted by an analog-to-digital converter (ADC) 328 to digital I and/or Q signals for digital signal processing.

Certain transceivers may employ a variable-frequency oscillator (e.g., a voltage-controlled oscillator (VCO) or a digitally controlled oscillator (DCO)) to generate a stable, tunable LO signal with a particular tuning range. Thus, the transmit LO signal may be produced by a TX frequency synthesizer 318, which may be buffered or amplified by amplifier 320 before being mixed with the baseband signals in the mixer 312. Similarly, the receive LO signal may be produced by an RX frequency synthesizer 330, which may be buffered or amplified by amplifier 332 before being mixed with the RF signals in the mixer 324. For certain aspects, a single frequency synthesizer may be used for both the TX path 302 and the RX path 304. In certain aspects, the TX frequency synthesizer 318 and/or RX frequency synthesizer 330 may include a frequency multiplier, such as a frequency doubler, that is driven by an oscillator (e.g., a VCO) in the frequency synthesizer.

While FIGS. 1-3 provide wireless communications as an example application in which certain aspects of the present disclosure may be implemented to facilitate understanding, certain aspects described herein may be used in any of various other suitable systems.

### Example Techniques for Phase Interpolation

Certain aspects of the present disclosure are directed towards generating multi-phase baseband (BB) signals using an in-phase (I) and quadrature (Q) digital-to-analog converter (DAC). With the I and Q signals and the interpolated phases (e.g., I with a 45° phase offset (I45) and Q with a 45° phase offset (Q45)), a harmonic reject transmitter may be implemented to cancel (or at least reduce the magnitude of) various harmonics that impact out-of-band (OOB) spurious emissions. These harmonics may include counter-inter-modulation product 3 (CIM3), counter-inter-modulation product 5 (CIM5), a harmonic at three times the local oscillator (LO) frequency with inverted phase modulation compared to the fundamental tone, and/or a harmonic at five times the LO frequency without phase modulation inversion as compared to the fundamental tone. In some aspects, a current-mode interpolator interface may be used with an IQ DAC to provide harmonic cancelation with reduced signal loss and increased linearity associated with a BB filter (BBF) and mixer as compared to some conventional implementations.

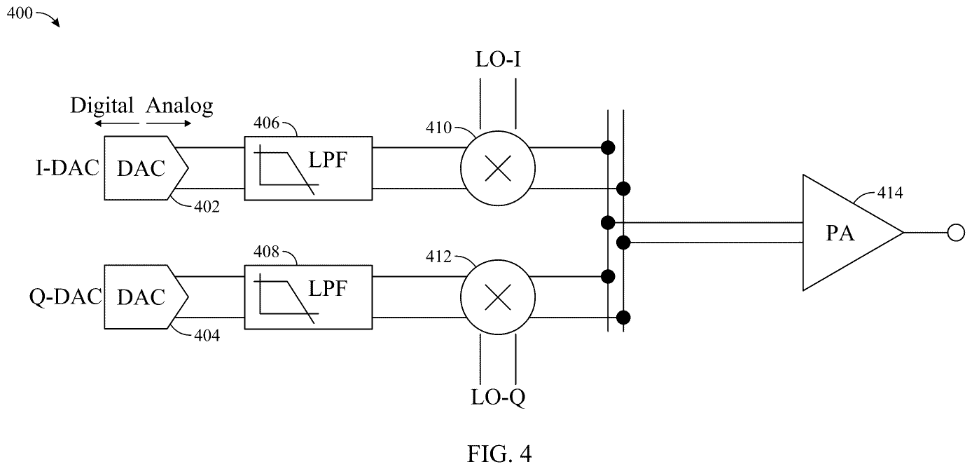

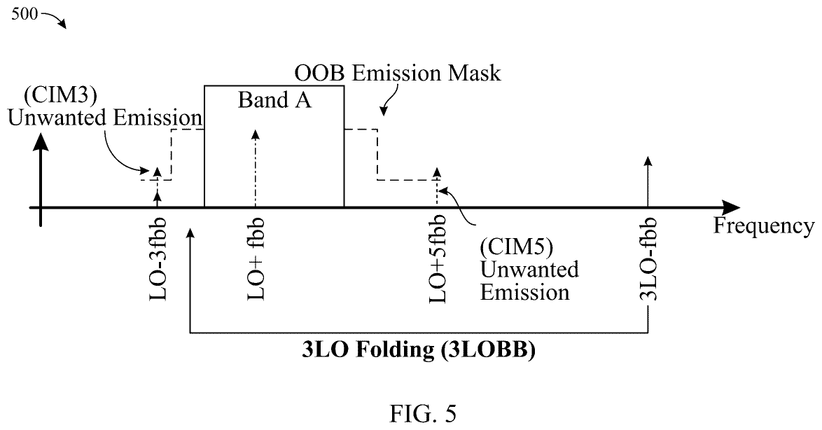

FIG. 4 is a block diagram of an example transmitter 400 with I and Q paths. As shown, the I path may include a DAC 402 (e.g., corresponding to the DAC 308 of FIG. 3) that receives a digital I signal and generates an analog I signal that is provided to a BBF 406 (e.g., corresponding to the BBF 310 of FIG. 3) implemented as a low-pass filter (LPF). The filtered I signal from the BBF 406 may be provided to a mixer 410 (e.g., corresponding to the mixer 312 of FIG. 3) to be mixed with an in-phase LO (LO-I) signal for upconversion. Similarly, the Q path may include a DAC 404 that receives a digital Q signal and generates an analog Q signal that is provided to a BBF 408 implemented as an LPF. In some cases, each BBF may be implemented using a trans-impedance amplifier (TIA). The filtered Q signal from the BBF 408 may be provided to a mixer 412 to be mixed with a quadrature LO (LO-Q) signal for upconversion. The upconverted I and Q signals from respective mixers 410, 412 may be combined and provided to the PA 414 (e.g., corresponding to the PA 316) for amplification. Non-linearity associated with the analog portion of the DACs, BBFs, and mixers may result in harmonics as shown in FIG. 5.

FIG. 5 is a graph 500 showing various harmonics around an operating band (labeled “Band A”). The transmitter 400 may have a fundamental frequency equal to the LO frequency plus fbb. As shown, the harmonics may include a harmonic at a frequency equal to the LO frequency minus three times fbb (LO-3fbb, also referred to as CIM3) and/or a harmonic at a frequency equal to the LO frequency five times fbb (LO-5fbb, also referred to as CIM5). The magnitude of the harmonics may be greater than the OOB emission mask, as shown. The OOB emission mask may define the permissible amount of emissions outside the operating bandwidth. The harmonics may also include a harmonic at a frequency equal to 3LO-fbb, which may be far from the operating band in the frequency domain. However, the 3LO-fbb harmonic may mix with the fundamental frequency in the PA and fold back onto the CIM3 frequency as shown.

In some cases, to cancel (or at least reduce the magnitude of) the harmonics, I, Q, I with a 45° phase offset (I45), and Q with a 45° phase offset (Q45) signal may be used. For example, a voltage interpolator may be used to generate I, Q, I45, and Q45 signals from the filtered I and Q signals at the respective outputs of BBFs 406, 408. A multi-phase BB signal may be generated at the mixer input using a voltage-mode resistive interpolator to cancel the CIM3, CIM5, 3LOBB, and 5LOBB harmonics. In this manner, the linearity associated with the mixer switches may be increased. However, a low-impedance node at the output of the interpolator may be created due to the voltage interpolation, resulting in the usage of a large capacitive element for filtering that increases area consumption. Moreover, power loss may be increased in the BB domain, which may degrade the signal-to-noise ratio (SNR) associated with the transmitter.

In some cases, the multiple phases may be generated in the digital domain using digital interpolation. In this case, the linearization interface starts at the DAC input, and thus, no passive interpolation may be used at the mixer interface. Thus, a high-impedance node (e.g., at the output of the interpolator) that is desirable for lowering the capacitor area used for filtering may be achieved. However, implementing separate paths for I, Q, I45, and Q45 signals starting from the digital domain may involve using separate DACs for each path, increasing the area consumption for the transmitter.

Some aspects of the present disclosure are directed towards techniques for harmonic cancellation (or at least reduction) in the current domain. Multi-phase signals (I, Q, I45, and Q45 signals) may be generated using a current-domain resistive interpolator, reducing power consumption and providing a high-impedance node at the mixer interface that allows for a reduction in area consumption.

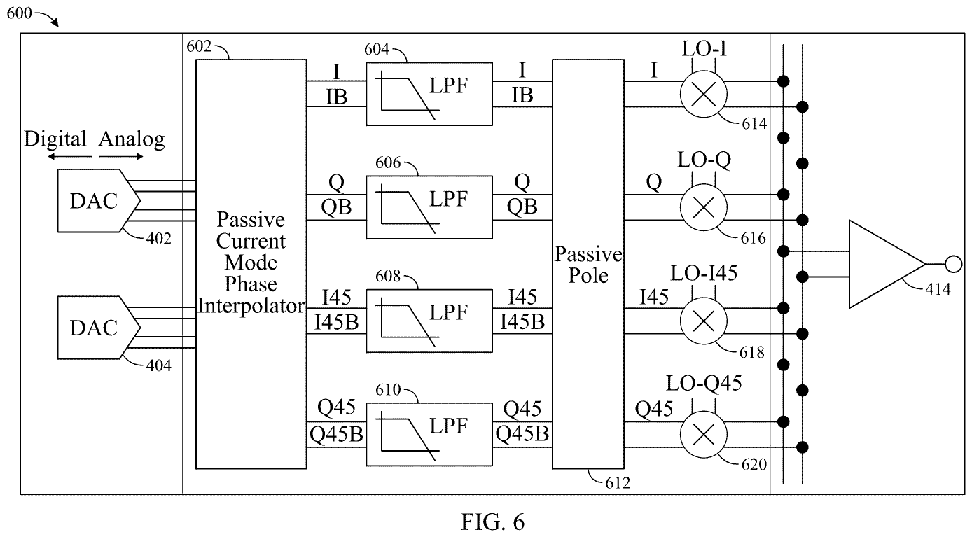

FIG. 6 is a block diagram of an example transmitter 600 including current-mode DACs with a current-mode resistive interpolator 602 (e.g., a passive interpolator), in accordance with certain aspects of the present disclosure. A current-mode DAC generally refers to a DAC with a high-impedance output where the amount of output current from the DAC represents a digital input code provided to the DAC. An I DAC may generate an I current and a complementary I (IB) current, and a Q DAC may generate a Q current and a complementary Q (QB) current.

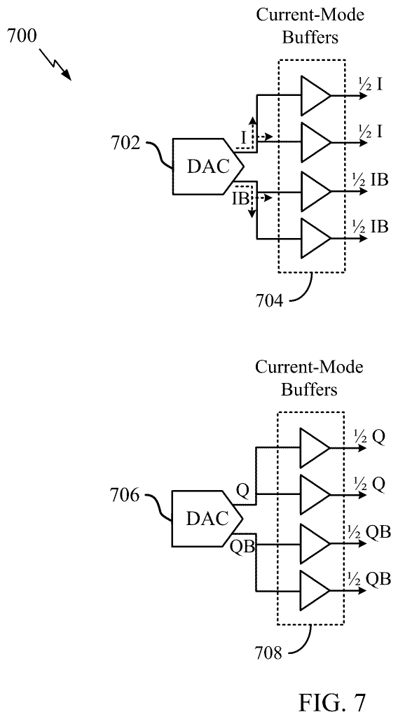

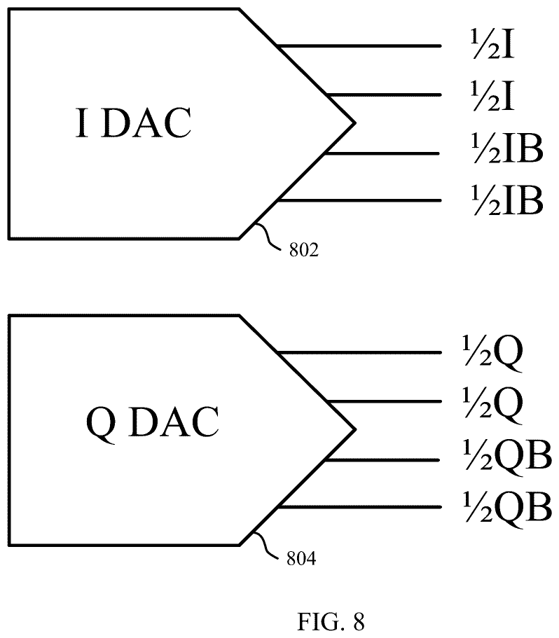

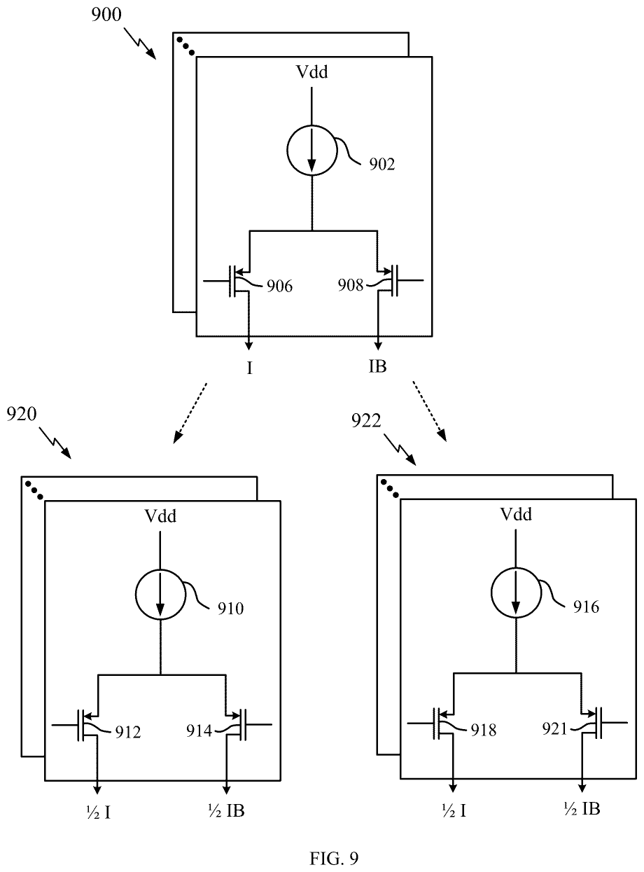

In some aspects, I and Q currents with a magnitude that is one-half of a full-scale current may be generated to facilitate current-mode interpolation. For example, as described in more detail with respect to FIGS. 8 and 9, the analog portion of each DAC may be implemented with two DAC cores where each DAC core includes a set of current-steering cells to generate the output currents of the DAC. A first DAC core of the I DAC may generate a current that is one-half of the full-scale I current (e.g., ½ I current) and a current that is one-half of the full-scale IB current (e.g., ½ IB current). A second DAC core of the I DAC may generate another current that is one-half of the full-scale I current (e.g., ½ I current) and another current that is one-half of the full-scale IB current (e.g., ½ IB current). Similarly, a first DAC core of the Q DAC may generate a current that is half of the full-scale Q current (e.g., ½ Q current) and a current that is half of the full-scale QB current (e.g., ½ QB current). A second DAC core of the Q DAC may generate another current that is half of the full-scale Q current (e.g., ½ Q current) and another current that is half of the full-scale QB current (e.g., ½ QB current). In some cases, to generate the half currents, each DAC may generate a full-scale current that may be split into two to generate the two half currents (e.g., two ½ I currents, two ½ IB currents, two ½ Q currents, and two ½ QB currents), as described in more detail herein with respect to FIG. 7.

The ½ I, ½ IB, ½ Q, and ½ QB currents may be provided to the interpolator 602 to generate I/IB currents, Q/QB currents, I45/I45B currents, and Q45/Q45B currents that are provided to respective BBFs 604, 606, 608, 610. The BBFs 604, 606, 608, 610 may generate filtered I, Q, I45, and Q45 signals that may be provided to a passive pole component 612 (e.g., filter) for generating I, Q, I45, and Q45 mixer input signals that are provided to respective mixers 614, 616, 618, 620 for upconversion. The upconverted signals from the mixers may be combined and provided to the PA 414 for amplification.

FIG. 7 is a block diagram of example digital-to-analog conversion circuitry 700 configured to generate currents using current splitting with buffers, in accordance with certain aspects of the present disclosure. As shown, the circuitry 700 may include a current-mode DAC 702 (e.g., corresponding to the DAC 402) that generates a full-scale I current and a full-scale IB current. The outputs of the DAC 702 may be coupled to current-mode buffers 704. The I current may be split and provided to respective current-mode buffers to generate a first ½ I current and a second ½ I current. The IB current may be split and provided to respective current-mode buffers to generate a first ½ IB current and a second ½ IB current.

Similarly, the circuitry 700 may include a current-mode DAC 706 (e.g., corresponding to the DAC 404) that generates a full-scale Q current and a full-scale QB current. The outputs of the DAC 706 may be coupled to current-mode buffers 708. The Q current may be split and provided to respective current-mode buffers to generate a first ½ Q current and a second ½ Q current. The QB current may be split and provided to respective current-mode buffers to generate a first ½ QB current and a second ½ QB current. The ½ I, ½ IB, ½ Q, and ½ QB currents may be provided to the current-mode interpolator 602 to generate multi-phase signals, as described.

FIG. 8 illustrates an I DAC 802 and a Q DAC 804, each including two DAC cores configured to generate one-half full-scale currents, in accordance with certain aspects of the present disclosure. As shown, the I DAC 802 (e.g., corresponding to DAC 402 of FIG. 4) may generate a first ½ I current, a second ½ I current, a first ½ IB current, and a second ½ IB current. The Q DAC 804 (e.g., corresponding to DAC 404 of FIG. 4) may generate a first ½ Q current, a second ½ Q current, a first ½ QB current, and a second ½ QB current. Each of the DACs may be a current-mode DAC with two DAC cores, as described. Each of the two DAC cores may include a set of current-steering cells as shown in FIG. 9.

FIG. 9 is a block diagram of example current-steering cells of a DAC, in accordance with certain aspects of the present disclosure. A current-mode DAC may include a set of current-steering cells 900 for generating a full-scale current (e.g., I current or Q current) and a complementary full-scale current (e.g., IB current or QB current). Each of the cells may include a current source 902 coupled to current-steering switches 906, 908 (e.g., implemented via p-type metal-oxide-semiconductor (PMOS) transistors). Based on a digital input code, the current-steering switches 906, 908 may be controlled to steer the current from the current source 902 to respective outputs of the cell (e.g., I and IB outputs). The outputs of the current-steering cells 900 may be combined to generate a current (e.g., I or Q) and a complementary current (e.g., IB or QB).

In some aspects of the present disclosure, the DAC may be implemented using two DAC cores (e.g., replica cores) including respective sets of current-steering cells 920, 922. Each of the current-steering cells 920 may include a current source 910 coupled to current-steering switches 912, 914, where the current-steering cells 920 generate a set of ½ I and ½ IB currents. The current source 910 of the current-steering cells 920 may source a current such that the generated I currents are one-half the full-scale I current that would be otherwise generated by the current-steering cells 900. Similarly, each of the current-steering cells 922 may include a current source 916 coupled to current-steering switches 918, 921, where the current-steering cells 922 generate another set of ½ I and ½ IB currents. Thus, the DAC including the current-steering cells 920, 922 may generate two ½ I currents and two ½ IB currents. A Q DAC may be implemented in a similar manner to generate two ½ Q currents and two ½ QB currents. The ½ I, ½ Q, ½ IB, and ½ QB currents may be provided to a current-mode resistive interpolator (e.g., interpolator 602 of FIG. 6) to generate I, I45, Q, and Q45 currents as described herein.

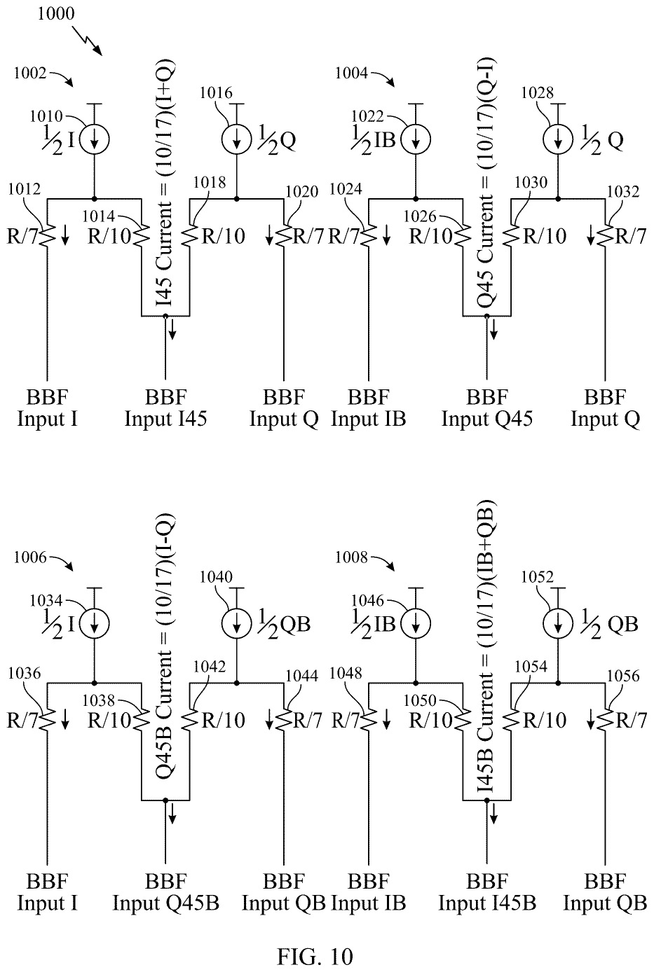

FIG. 10 is a circuit diagram of an example current-mode resistive interpolator 1000 (e.g., corresponding to the interpolator 602 of FIG. 6), in accordance with certain aspects of the present disclosure. For example, the interpolator 1000 may include a set of resistive current dividers 1002, 1004, 1006, 1008, where each resistive current divider is coupled to two current sources, each supplying a current that is split to flow across two resistive elements. For example, the current divider 1002 may be coupled to a current source 1010 representing the DAC output providing the ½ I current. The current source 1010 is coupled to resistive elements 1012, 1014, where the ½ I current is split and flows across resistive elements 1012, 1014 as shown. The resistance of the resistive element 1012 may be R/7, and the resistance of the resistive element 1014 may be R/14, where R is any suitable resistance value (e.g., 1 kΩ). The current divider 1002 may be coupled to a current source 1016 representing the DAC output providing the ½ Q current. The current source 1016 is coupled to resistive elements 1018, 1020, where the ½ Q current is split and flows across resistive elements 1018, 1020 as shown. The resistance of the resistive element 1020 may be R/7, and the resistance of the resistive element 1014 may be R/14, where R is any suitable resistance value (e.g., 1 kΩ). The current across resistive element 1012 may be an I current (e.g., having a magnitude of 7/17 times the full-scale I current) and provided to the I input of a BBF (e.g., the BBF 604), and the current across resistive element 1020 may be a Q current (e.g., having a magnitude of 7/17 times the full-scale Q current) and provided to the Q input of a BBF (e.g., the BBF 606). As shown, the currents across resistive elements 1014, 1018 may be combined at a combination node 1001 to generate a combined current that may be an I45 current (e.g., having a magnitude of 10/17 times the sum of the full-scale I and Q currents) provided to the I45 input of a BBF (e.g., the BBF 608).

The resistive current dividers 1004, 1006, 1008 may be implemented in a similar manner as the resistive current divider 1002. For example, the divider 1004 may be coupled to a current source 1022 representing the ½ IB current provided by the I DAC, where the current source 1022 is coupled to resistive elements 1024, 1026. The divider 1004 may be coupled to a current source 1028 representing the ½ Q current provided by the Q DAC, where the current source 1028 is coupled to resistive elements 1030, 1032. The current across the resistive element 1024 may be an IB current provided to the IB input of a BBF (e.g., the BBF 604), the current across the resistive element 1032 may be the Q current provided to the Q input of a BBF (e.g., the BBF 606), and the currents across the resistive elements 1026, 1030 are combined to generate the Q45 current provided to the Q45 input of a BBF (e.g., the BBF 606).

The divider 1006 may be coupled to a current source 1034 representing the ½ I current provided by the I DAC, where the current source 1034 is coupled to resistive elements 1036, 1038. The divider 1006 may also be coupled to a current source 1040 representing the ½ QB current provided by the Q DAC, where the current source 1040 is coupled to resistive elements 1042, 1044. The current across the resistive element 1036 may be the I current provided to the I input of a BBF (e.g., the BBF 604), the current across the resistive element 1044 may be the QB current provided to the QB input of a BBF (e.g., the BBF 606), and the currents across the resistive elements 1038, 1042 are combined to generate a Q45B current provided to the Q45B input of a BBF (e.g., the BBF 610).

The divider 1008 may be coupled to a current source 1046 representing the ½ IB current provided by the I DAC, where the current source 1046 is coupled to resistive elements 1048, 1050. The divider 1008 may be coupled to a current source 1052 representing the ½ QB current provided by the Q DAC, where the current source 1052 is coupled to resistive elements 1054, 1056. The current across the resistive element 1048 may be the IB current provided to the IB input of a BBF (e.g., the BBF 604), the current across the resistive element 1056 may be the QB current provided to the QB input of a BBF (e.g., the BBF 606), and the currents across the resistive elements 1050, 1054 are combined to generate I45B current provided to the I45B input of a BBF (e.g., the BBF 608).

As shown, the I input of a BBF (e.g., the BBF 604) receives the combination of the I currents across resistive elements 1012, 1036. The IB input of a BBF (e.g., the BBF 604) receives the combination of the IB currents across resistive elements 1024, 1048. The Q input of a BBF (e.g., the BBF 606) receives the combination of the Q currents across resistive elements 1020, 1032. The QB input of a BBF (e.g., the BBF 606) receives the combination of the QB currents across resistive elements 1044, 1056.

The interpolator (e.g. the interpolator 602 or 1000) may be designed to provide the same impedance at the various inputs and outputs of the interpolator, facilitating the efficient operation of the digital-to-analog conversion circuitry and BBFs. For example, the input of the interpolator 1000 receiving the ½ I current (e.g., represented by current source 1010) may see the same impedance (e.g., R/17) as the input receiving the ½ Q current (e.g., represented by current source 1016). In some cases, any gain loss due to the interpolator may be compensated for by increasing the TIA gain of the BBFs.

In some aspects, the interpolator may be implemented to provide duplicate I and Q signals instead of I, Q, I45, and Q45 signals. For instance, at least some of the resistive elements 1012, 1014, 1018, 1020, 1024, 1026, 1030, 1032, 1036, 1038, 1042, 1044, 1048, 1050, 1054, 1056 may be implemented as variable resistive elements. The resistances of these variable resistive elements may be adjusted so that the interpolator provides another set of I, IB, Q, and QB signals instead of the I45, I45B, Q45, Q45B signals. In this manner, BBFs 608, 610 may also receive I and Q signals that are upconverted by mixers 618, 620. The unconverted I and Q signals from the mixers 614, 616 and the upconverted I and Q signals from the mixers 618, 620 may be combined at the input of the PA 414. Thus, the interpolator may be operated in a first configuration to provide a transmitter with harmonic rejection using I, Q, I45, and Q45 signals or in a second configuration to provide a transmitter without the harmonic rejection as may be useful for some applications.

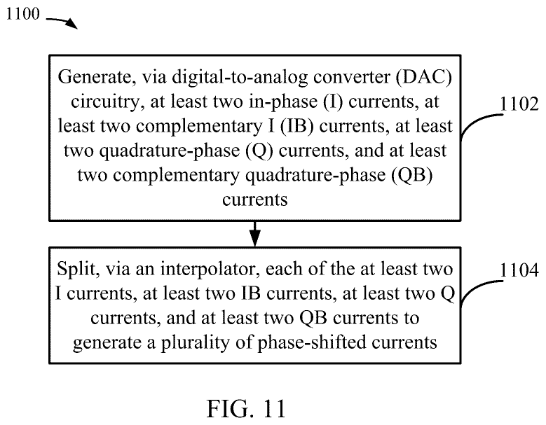

FIG. 11 is a flow diagram illustrating example operations 1100 for phase interpolation, in accordance with certain aspects of the present disclosure. The operations 1100 may be performed, for example, by DAC and interpolation circuitry (e.g., DAC 402, DAC 404, and interpolator 602 of FIG. 6) and that may be part of a transmitter such as the transmitter 600 of FIG. 6.

At block 1102, the circuitry may generate (e.g., via DAC circuitry such as DAC 402 and/or DAC 404) at least two in-phase (I) currents, at least two complementary I (IB) currents, at least two quadrature-phase (Q) currents, and at least two complementary quadrature-phase (QB) currents. At block 1104, the circuitry may split (e.g., via an interpolator such as the interpolator 602) each of the at least two I currents, at least two IB currents, at least two Q currents, and at least two QB currents to generate a plurality of phase-shifted (e.g., and scaled) currents.

In some cases, the DAC circuitry may include a first DAC (e.g., DAC 402) configured to generate the at least two in-phase (I) currents and the at least two IB currents, and a second DAC (e.g., DAC 404) configured to generate the at least two Q currents and the at least two QB currents.

In some cases, each of the plurality of phase-shifted currents comprises a phase-shifted I current (e.g., I45 current), a phase-shifted Q current (e.g., Q45 current), a phase-shifted IB current (e.g., I45B current), and a phase-shifted QB current (e.g., Q45B). In some cases, the circuitry may (e.g., via the interpolator): split one of the I currents and one of the Q currents to generate the phase-shifted I current; split one of the IB currents and another one of the Q currents to generate the phase-shifted Q current; split another one of the I currents and one of the QB currents to generate the phase-shifted QB current; and split another one of the IB currents and another one of the QB currents to generate the phase-shifted IB current.

In some cases, the circuitry may (e.g., via the interpolator 602 or 1000), split one of the at least two I currents (e.g., from current source 1010) to provide an I output current (e.g., flowing across resistive element 1012) to an I output of the interpolator (e.g., which may be provided to an I input of BBF 604) and a phase-shifted I output current (e.g., I45 current) to a phase-shifted I output (I45 output) of the interpolator. The circuitry may (e.g., via the interpolator 602 or 1000), split one of the at least two Q currents (e.g., from current source 1016) to provide the phase-shifted I output current to the phase-shifted I output of the interpolator and a Q output current to a Q output of the interpolator. In some aspects, the circuitry may (e.g., via the interpolator 602 or 1000), split one of the at least two IB currents (e.g., from current source 1022) to provide an IB current at an IB output of the interpolator and a phase-shifted Q current (e.g., Q45 current) to a phase-shifted Q output (e.g., Q45 output) of the interpolator, and split one of the at least two Q currents (e.g., from current source 1028) to provide the phase-shifted Q current to the phase-shifted Q output of the interpolator and another Q current to the Q output. In some aspects, the circuitry may (e.g., via the interpolator 602 or 1000), split another one of the at least two I currents (e.g., from current source 1034) to provide another I current to the I output of the interpolator and a phase-shifted QB current (e.g., Q45B current) to a phase-shifted QB output of the interpolator, and split one of the at least two QB currents (e.g., from current source 1040) to provide the phase-shifted QB current to the phase-shifted QB output of the interpolator and a QB current to a QB output of the interpolator. In some aspects, the circuitry may (e.g., via the interpolator 602 or 1000), split another one of the at least two IB currents (e.g., from current source 1046) to provide another IB current to the IB output and a phase-shifted IB current (e.g., I45B current) to a phase-shifted IB output (e.g., I45B output) of the interpolator, and split another one of the at least two QB currents (e.g., from current source 1052) to provide the phase-shifted IB current to the phase-shifted IB output of the interpolator and a QB current to the QB output of the interpolator.

In some aspects, the circuitry may (e.g., via the interpolator 602 or 1000), generate the plurality of phase-shifted currents when operating in a first configuration, or generate at least two I output currents and at least two Q output currents when operating in a second configuration.

### Example Aspects

Aspect 1: An apparatus for phase interpolation, comprising: digital-to-analog converter (DAC) circuitry configured to generate at least two in-phase (I) currents, at least two complementary I (IB) currents, at least two quadrature (Q) currents, and at least two complementary Q (QB) currents; and an interpolator configured to split each of the at least two I currents, the at least two IB currents, the at least two Q currents, and the at least two QB currents to generate a plurality of phase-shifted currents.

Aspect 2: The apparatus of Aspect 1, wherein the DAC circuitry includes: a first DAC configured to generate the at least two I currents and the at least two IB currents; and a second DAC configured to generate the at least two Q currents and the at least two QB currents.

Aspect 3: The apparatus of Aspect 2, wherein the first DAC is configured generate the at least two I currents using a same digital input signal.

Aspect 4: The apparatus according to any of Aspects 1-3, wherein: the plurality of phase-shifted currents comprises a phase-shifted I current, a phase-shifted Q current, a phase-shifted IB current, and a phase-shifted QB current; and the interpolator is configured to: split on one of the I currents and one of the Q currents to generate the phase-shifted I current; split on one of the IB currents and another one of the Q currents to generate the phase-shifted Q current; split on another one of the I currents and one of the QB currents to generate the phase-shifted QB current; and split on another one of the IB currents and another one of the QB currents to generate the phase-shifted IB current.

Aspect 5: The apparatus according to any of Aspects 1-4, wherein the interpolator is configured to: split one of the at least two I currents to provide an I output current to an I output of the interpolator and a phase-shifted I output current to a phase-shifted I output of the interpolator; and split one of the at least two Q currents to provide the phase-shifted I output current to the phase-shifted I output of the interpolator and a Q output current to a Q output of the interpolator.

Aspect 6: The apparatus of Aspect 5, wherein the interpolator is configured to: split one of the at least two IB currents to provide an IB current at an IB output of the interpolator and a phase-shifted Q current to a phase-shifted Q output of the interpolator; and split one of the at least two Q currents to provide the phase-shifted Q current to the phase-shifted Q output of the interpolator and another Q current to the Q output.

Aspect 7: The apparatus of Aspect 6, wherein the interpolator is configured to: split another one of the at least two I currents to provide another I current to the I output of the interpolator and a phase-shifted QB current to a phase-shifted QB output of the interpolator; and split one of the at least two QB currents to provide the phase-shifted QB current to the phase-shifted QB output of the interpolator and a QB current to a QB output of the interpolator.

Aspect 8: The apparatus of Aspect 7, wherein the interpolator is configured to: split another one of the at least two IB currents to provide another IB current to the IB output and a phase-shifted IB current to a phase-shifted IB output of the interpolator; and split another one of the at least two QB currents to provide the phase-shifted IB current to the phase-shifted IB output of the interpolator and a QB current to the QB output of the interpolator.

Aspect 9: The apparatus according to any of Aspects 1-8, wherein the interpolator is configured to: generate the plurality of phase-shifted currents when operating in a first configuration; or generate at least two I output currents and at least two Q output currents when operating in a second configuration.

Aspect 10: A transmitter including the apparatus according to any of Aspects 1-9, the transmitter further comprising baseband filter circuitry configured to receive the plurality of phase-shifted currents and generate filtered phase-shifted signals based on the plurality of phase-shifted currents.

Aspect 11: The transmitter of Aspect 10, further comprising harmonic rejection mixer circuitry configured to receive the filtered phase-shifted signals and generate upconverted signals based on the filtered phase-shifted signals.

Aspect 12: The apparatus according to any of Aspects 1-11, wherein the interpolator comprises a current-mode interpolator including a resistive current divider configured to split each of the at least two I currents, the at least two IB currents, the at least two Q currents, and the at least two QB currents to generate the plurality of phase-shifted currents.

Aspect 13: An apparatus for phase interpolation, comprising: current-mode digital-to-analog converter (DAC) circuitry including at least two in-phase (I) outputs, at least two complementary I (IB) outputs, at least two quadrature (Q) outputs, and at least two complementary Q (QB) outputs; and a current-mode interpolator including multiple inputs coupled to the at least two I outputs, the at least two IB outputs, the at least two Q outputs, and the at least two QB outputs, respectively, wherein the current-mode interpolator includes split current paths coupled to each of the multiple inputs.

Aspect 14: The apparatus of Aspect 13, wherein each of the split current paths includes a resistive element.

Aspect 15: The apparatus of Aspect 13 or 14, wherein the DAC circuitry includes: a first DAC including the at least two in-phase (I) outputs and at least two complementary I (IB) outputs; and a second DAC including the at least two Q outputs and the at least two QB outputs.

Aspect 16: The apparatus according to any of Aspects 13-15, wherein the split current paths include: a path coupled between one of the at least two I outputs and an I output of the current-mode interpolator; a path coupled between the one of the at least two I outputs and a phase-shifted I output of the current-mode interpolator; a path coupled between one of the at least two Q outputs and the phase-shifted I output of the current-mode interpolator; and a path coupled between the one of the at least two Q outputs and a Q output of the current-mode interpolator.

Aspect 17: The apparatus of Aspect 16, wherein the split current paths include: a path coupled between one of the at least two IB outputs and an IB output of the current-mode interpolator; a path coupled between the one of the at least two IB outputs and a phase-shifted Q output of the current-mode interpolator; a path coupled between another one of the at least two Q outputs and the phase-shifted Q output of the current-mode interpolator; and a path coupled between the other one of the at least two Q outputs and the Q output of the current-mode interpolator.

Aspect 18: The apparatus of Aspect 17, wherein the split current paths include: a path coupled between another one of the at least two I outputs and the I output of the current-mode interpolator; a path coupled between the other one of the at least two I outputs and a phase-shifted QB output of the current-mode interpolator; a path coupled between one of the at least two QB outputs and the phase-shifted QB output of the current-mode interpolator; and a path coupled between the one of the at least two QB outputs and a QB output of the current-mode interpolator.

Aspect 19: The apparatus of Aspect 18, wherein the split current paths include: a path coupled between another one of the at least two IB outputs and an IB output of the current-mode interpolator; a path coupled between the other one of the at least two IB outputs and a phase-shifted IB output of the current-mode interpolator; a path coupled between the other one of the at least two QB outputs and the phase-shifted IB output of the current-mode interpolator; and a path coupled between the other one of the at least two QB outputs and the QB output of the current-mode interpolator.

Aspect 20: A method for phase interpolation, comprising: generating, via digital-to-analog converter (DAC) circuitry, at least two in-phase (I) currents, at least two complementary I (IB) currents, at least two quadrature (Q) currents, and at least two complementary Q (QB) currents; and split, via an interpolator, each of the at least two I currents, the at least two IB currents, the at least two Q currents, and the at least two QB currents to generate a plurality of phase-shifted currents.

### Additional Considerations

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. An apparatus for phase interpolation, comprising:
digital-to-analog converter (DAC) circuitry configured to generate at least two in-phase (I) currents, at least two complementary I (IB) currents, at least two quadrature (Q) currents, and at least two complementary Q (QB) currents; and
an interpolator configured to split each of the at least two I currents, the at least two IB currents, the at least two Q currents, and the at least two QB currents to generate a plurality of phase-shifted currents.

2. The apparatus of claim 1, wherein the DAC circuitry includes:
a first DAC configured to generate the at least two I currents and the at least two IB currents; and
a second DAC configured to generate the at least two Q currents and the at least two QB currents.

3. The apparatus of claim 2, wherein the first DAC is configured generate the at least two I currents using a same digital input signal.

4. The apparatus of claim 1, wherein:
the plurality of phase-shifted currents comprises a phase-shifted I current, a phase-shifted Q current, a phase-shifted IB current, and a phase-shifted QB current; and
the interpolator is configured to:
split on one of the I currents and one of the Q currents to generate the phase-shifted I current;
split on one of the IB currents and another one of the Q currents to generate the phase-shifted Q current;
split on another one of the I currents and one of the QB currents to generate the phase-shifted QB current; and
split on another one of the IB currents and another one of the QB currents to generate the phase-shifted IB current.

5. The apparatus of claim 1, wherein the interpolator is configured to:
split one of the at least two I currents to provide an I output current to an I output of the interpolator and a phase-shifted I output current to a phase-shifted I output of the interpolator; and
split one of the at least two Q currents to provide the phase-shifted I output current to the phase-shifted I output of the interpolator and a Q output current to a Q output of the interpolator.

6. The apparatus of claim 5, wherein the interpolator is configured to:
split one of the at least two IB currents to provide an IB current at an IB output of the interpolator and a phase-shifted Q current to a phase-shifted Q output of the interpolator; and
split one of the at least two Q currents to provide the phase-shifted Q current to the phase-shifted Q output of the interpolator and another Q current to the Q output.

7. The apparatus of claim 6, wherein the interpolator is configured to:
split another one of the at least two I currents to provide another I current to the I output of the interpolator and a phase-shifted QB current to a phase-shifted QB output of the interpolator; and
split one of the at least two QB currents to provide the phase-shifted QB current to the phase-shifted QB output of the interpolator and a QB current to a QB output of the interpolator.

8. The apparatus of claim 7, wherein the interpolator is configured to:
split another one of the at least two IB currents to provide another IB current to the IB output and a phase-shifted IB current to a phase-shifted IB output of the interpolator; and
split another one of the at least two QB currents to provide the phase-shifted IB current to the phase-shifted IB output of the interpolator and a QB current to the QB output of the interpolator.

9. The apparatus of claim 1, wherein the interpolator is configured to:
generate the plurality of phase-shifted currents when operating in a first configuration; or
generate at least two I output currents and at least two Q output currents when operating in a second configuration.

10. A transmitter including the apparatus of claim 1, the transmitter further comprising baseband filter circuitry configured to receive the plurality of phase-shifted currents and generate filtered phase-shifted signals based on the plurality of phase-shifted currents.

11. The transmitter of claim 10, further comprising harmonic rejection mixer circuitry configured to receive the filtered phase-shifted signals and generate upconverted signals based on the filtered phase-shifted signals.

12. The apparatus of claim 1, wherein the interpolator comprises a current-mode interpolator including a resistive current divider configured to split each of the at least two I currents, the at least two IB currents, the at least two Q currents, and the at least two QB currents to generate the plurality of phase-shifted currents.

13. An apparatus for phase interpolation, comprising:
current-mode digital-to-analog converter (DAC) circuitry including at least two in-phase (I) outputs, at least two complementary I (IB) outputs, at least two quadrature (Q) outputs, and at least two complementary Q (QB) outputs; and
a current-mode interpolator including multiple inputs coupled to the at least two I outputs, the at least two IB outputs, the at least two Q outputs, and the at least two QB outputs, respectively, wherein the current-mode interpolator includes split current paths coupled to each of the multiple inputs.

14. The apparatus of claim 13, wherein each of the split current paths includes a resistive element.

15. The apparatus of claim 13, wherein the DAC circuitry includes:
a first DAC including the at least two in-phase (I) outputs and at least two complementary I (IB) outputs; and
a second DAC including the at least two Q outputs and the at least two QB outputs.

16. The apparatus of claim 13, wherein the split current paths include:
a path coupled between one of the at least two I outputs and an I output of the current-mode interpolator;
a path coupled between the one of the at least two I outputs and a phase-shifted I output of the current-mode interpolator;
a path coupled between one of the at least two Q outputs and the phase-shifted I output of the current-mode interpolator; and
a path coupled between the one of the at least two Q outputs and a Q output of the current-mode interpolator.

17. The apparatus of claim 16, wherein the split current paths include:
a path coupled between one of the at least two IB outputs and an IB output of the current-mode interpolator;
a path coupled between the one of the at least two IB outputs and a phase-shifted Q output of the current-mode interpolator;
a path coupled between another one of the at least two Q outputs and the phase-shifted Q output of the current-mode interpolator; and
a path coupled between the other one of the at least two Q outputs and the Q output of the current-mode interpolator.

18. The apparatus of claim 17, wherein the split current paths include:
a path coupled between another one of the at least two I outputs and the I output of the current-mode interpolator;
a path coupled between the other one of the at least two I outputs and a phase-shifted QB output of the current-mode interpolator;
a path coupled between one of the at least two QB outputs and the phase-shifted QB output of the current-mode interpolator; and
a path coupled between the one of the at least two QB outputs and a QB output of the current-mode interpolator.

19. The apparatus of claim 18, wherein the split current paths include:
a path coupled between another one of the at least two IB outputs and an IB output of the current-mode interpolator;
a path coupled between the other one of the at least two IB outputs and a phase-shifted IB output of the current-mode interpolator;
a path coupled between the other one of the at least two QB outputs and the phase-shifted IB output of the current-mode interpolator; and
a path coupled between the other one of the at least two QB outputs and the QB output of the current-mode interpolator.

20. A method for phase interpolation, comprising:
generating, via digital-to-analog converter (DAC) circuitry, at least two in-phase (I) currents, at least two complementary I (IB) currents, at least two quadrature (Q) currents, and at least two complementary Q (QB) currents; and
split, via an interpolator, each of the at least two I currents, the at least two IB currents, the at least two Q currents, and the at least two QB currents to generate a plurality of phase-shifted currents.
